(19) United States
(12) Patent Application Publication
(10) Pub. No.: US 2009/0218633 A1
(43) Pub. Date: Sep. 3, 2009

(54) CMOS DEVICE COMPRISING AN NMOS TRANSISTOR WITH RECESSED DRAIN AND SOURCE AREAS AND A PMOS TRANSISTOR HAVING A SILICON/GERMANIUM MATERIAL IN THE DRAIN AND SOURCE AREAS

(76) Inventors: Jan Hoentschel, Dresden (DE); Andy Wei, Dresden (DE); Uwe Griebenow, Markkleeberg (DE)

Correspondence Address: WILLIAMS, MORGAN & AMERSON, 10333 RICHMOND, SUITE 1100, HOUSTON, TX, 77042, US

(21) Appl. No.: 12/258,660

(22) Filed: Oct. 27, 2008

(30) Foreign Application Priority Data
Feb. 29, 2008 (DE) 10 2008 011 814.1

(51) Int. Cl. H01L 27/092; H01L 21/8238

(52) U.S. Cl. 257/369; 438/199; 257/E27.062; 257/E21.632

(57) ABSTRACT

A recessed transistor configuration may be provided selectively for one type of transistor, such as N-channel transistors, thereby enhancing strain-inducing efficiency and series resistance, while a substantially planar configuration or raised drain and source configuration may be provided for other transistors, such as P-channel transistors, which may also include a strained semiconductor alloy, while nevertheless providing a high degree of compatibility with CMOS techniques. For this purpose, an appropriate masking regime may be provided to efficiently cover the gate electrode of one transistor type during the formation of the corresponding recesses, while completely covering the other type of transistor.

### BACKGROUND

1. Field of the Disclosure

Generally, the subject matter disclosed herein relates to the formation of integrated circuits, and, more particularly, to the formation of transistors having strained channel regions by using stress sources, such as stressed overlayers, a strained semiconductor alloy in drain and source areas, to enhance charge carrier mobility in the channel region of a MOS transistor.

2. Description of the Related Art

Generally, a plurality of process technologies are currently practiced in the field of semiconductor production, wherein, for complex circuitry, such as microprocessors, storage chips and the like, CMOS technology is currently the most promising approach due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed near the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the overall conductivity of the channel region substantially determines the performance of the MOS transistors. Thus, the reduction of the channel length is a dominant design criterion for accomplishing an increase in the operating speed and packing density of the integrated circuits.

The continuing shrinkage of the transistor dimensions, however, involves a plurality of issues associated therewith that have to be addressed so as to not unduly offset the advantages obtained by steadily decreasing the channel length of MOS transistors. One major problem in this respect is to provide low sheet and contact resistivity in drain and source regions and any contacts connected thereto and to maintain channel controllability. For example, reducing the channel length may necessitate an increase of the capacitive coupling between the gate electrode and the channel region, which may call for reduced thickness of the gate insulation layer. Presently, the thickness of silicon dioxide based gate insulation layers is in the range of 1-2 nm, wherein a further reduction may be less desirable in view of leakage currents which typically exponentially increase when reducing the gate dielectric thickness.

The continuous size reduction of the critical dimensions, i.e., the gate length of the transistors, necessitates the adaptation and possibly the new development of highly complex process techniques concerning the above-identified problems. It has, therefore, been proposed to improve transistor performance by enhancing the channel conductivity of the transistor elements by increasing the charge carrier mobility in the channel region for a given channel length, thereby offering the potential for achieving a performance improvement that is comparable with the advance to a future technology node, while avoiding or at least postponing many of the above-mentioned problems, such as gate dielectric scaling. One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, for standard silicon substrates, creating tensile strain in the channel region increases the mobility of electrons, which in turn may directly translate into a corresponding increase in the conductivity and, thus, drive current and operating speed. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials, while many of the well-established manufacturing techniques may still be used.

According to one promising approach for creating strain in the channel region of transistor elements, the dielectric material that is formed above the basic transistor structure may be provided in a highly stressed state to induce a desired type of strain at the transistor and in particular in the channel region thereof. For example, the transistor structures are typically enclosed in an interlayer dielectric material, which may provide the desired mechanical and electrical integrity of the individual transistor structures and which may provide a platform for the formation of additional wiring layers, which are typically required for providing the electrical interconnections between the individual circuit elements. That is, a plurality of wiring levels or metallization layers may typically be provided which may include horizontal metal lines and vertical vias including appropriate conductive materials for establishing the electrical connections. Consequently, an appropriate contact structure has to be provided which connects the actual circuit elements, such as transistors, capacitors and the like, or respective portions thereof, with the very first metallization layer. For this purpose, the interlayer dielectric material has to be appropriately patterned in order to provide respective openings connecting to the desired contact areas of the circuit elements, which may typically be accomplished by using an etch stop material in combination with the actual interlayer dielectric material.

For example, silicon dioxide is a well-established interlayer dielectric material in combination with silicon nitride, which may act as an efficient etch stop material during the formation of the contact openings. Consequently, the etch stop material, i.e., the silicon nitride material, is in close contact with the basic transistor structure and thus may be efficiently used for inducing strain in the transistors, in particular as silicon nitride may be deposited on the basis of well-established plasma enhanced chemical vapor deposition (PECVD) techniques with high internal stress. For instance, silicon nitride may be deposited with high internal compressive stress of up to 2 GPa and even higher by selecting appropriate deposition parameters. On the other hand, a moderately high internal tensile stress level may be created to 1 GPa and higher by appropriately adjusting the process parameters, for instance, in particular, the degree of ion bombardment during the deposition of the silicon nitride material. Consequently, the magnitude of the strain created in the channel region of a transistor element may depend on the internal stress level of the dielectric etch stop material and the thickness of stressed dielectric material in combination with the effective offset of the highly stressed dielectric material with respect to the channel region. Consequently, in view of enhancing transistor performance, it may be desirable to increase the internal stress level and also provide enhanced amounts of highly stressed dielectric material in the vicinity of the transistor element, while also positioning the stressed dielectric material as closely as possible to the channel region. It turns out, however, that the internal stress levels of silicon nitride material may be restricted by the overall deposition capabilities of presently available PECVD techniques, while the effective layer thickness may also be substantially determined by the basic transistor topography and the distance between neighboring circuit elements. Consequently, although providing significant advantages, the efficiency of the stress transfer mechanism may significantly depend on process and device specifics and may result in reduced performance gain for well-established standard transistor designs having gate lengths of 50 nm and less, since the given device topography and the gap fill capabilities of the respective deposition process, in combination with a moderately high offset of the highly stressed material from the channel region caused by sophisticated spacer structures, may reduce the finally obtained strain in the channel region.

For these reasons, it has been suggested to use a recessed transistor architecture, i.e., an architecture in which portions of drain and source regions are recessed with respect to the channel region in the vicinity of the interface between the channel and the gate insulation layer in order to allow the deposition of the highly stressed dielectric material at a height level that corresponds to the channel region, thereby efficiently enhancing the lateral stress transfer mechanism into the channel region. Although this strategy may result in increased transistor performance, it may, in some circumstances, not be desirable to apply this strategy to all transistor elements of a semiconductor device, since a recessed transistor configuration may offset the efficiency of other strain-inducing mechanisms, which may therefore result in a reduced overall transistor performance. For example, in some approaches, performance of transistors such as P-channel transistors may be enhanced by providing a semiconductor material, at least in portions of the drain and source areas, in such a manner that a desired type of strain may be generated in the adjacent channel region. For this purpose, frequently a silicon/germanium mixture or alloy may be used which may be epitaxially grown on a silicon template material, thereby creating a strained state of the silicon/germanium alloy, which may exert a certain stress on the adjacent channel region, thereby creating the desired type of strain therein. The magnitude of the strain in the channel region may be adjusted on the basis of the size of respective cavities in which the silicon/germanium alloy may be grown and by the amount of the germanium concentration in the semiconductor alloy. Since the respective strained semiconductor alloy may be positioned immediately adjacent to the channel region, a highly efficient strain-inducing mechanism may be provided, which may, however, be significantly affected by providing a recessed transistor configuration. That is, recessing the drain and source areas including the highly strained semiconductor alloy may effectively result in a reduction of strain, even if the removed strained semiconductor alloy may be replaced by a highly stressed dielectric silicon nitride material, as previously explained. Thus, an efficient strain-inducing mechanism for P-channel transistors on the basis of strained semiconductor alloys may not be fully compatible with a recessed transistor architecture, which may be highly advantageous with respect to N-channel transistors, since, for these transistors, strained semiconductor alloys, incorporated into the drain and source region, may be less efficient according to presently available technologies.

The present disclosure is directed to various methods and devices that may avoid, or at least reduce, the effects of one or more of the problems identified above.

### SUMMARY OF THE DISCLOSURE

The following presents a simplified summary of the disclosure in order to provide a basic understanding of some aspects disclosed herein. This summary is not an exhaustive overview, and it is not intended to identify key or critical elements of the invention or to delineate the scope of the invention. Its sole purpose is to present some concepts in a simplified form as a prelude to the more detailed description that is discussed later.

Generally, the subject matter disclosed herein relates to semiconductor devices and techniques for fabricating the same, wherein enhanced transistor performance may be obtained for one type of transistor, such as N-channel transistors, on the basis of a recessed transistor configuration, while substantially not unduly affecting other transistors, such as P-channel transistors, for which a recessed transistor configuration may not be desired. For this purpose, a technique may be provided which may provide a high degree of compatibility with sophisticated CMOS technologies, thereby enabling the formation of strained semiconductor alloys, such as strained silicon/germanium material, in drain and source areas of P-channel transistors in combination with advanced lateral dopant profiles which may typically be formed on the basis of sidewall spacer structures including two or more individual spacer elements. The selective recessing of portions of the drain and source areas may be accomplished by providing an appropriate masking regime for protecting gate electrodes of the transistor receiving the recessed drain and source configuration, while other transistors not receiving the recessed drain and source configuration may be efficiently masked by well-established lithography techniques compatible with the overall CMOS process flow. In some illustrative aspects disclosed herein, the mask of the gate electrode may be efficiently removed without requiring additional process steps compared to conventional CMOS strategies, in which the width of a sidewall spacer structure is to be reduced prior to forming metal silicide regions to reduce the overall series resistance and also reduce the lateral distance with respect to the channel region. Consequently, performance of both types of transistors, i.e., transistors having a recessed drain and source configuration and non-recessed transistors including additional strain-inducing mechanisms, may be enhanced, thereby providing significant overall gain in performance of CMOS devices.

One illustrative semiconductor device disclosed herein comprises an N-channel transistor formed above a substrate. The N-channel transistor comprises drain and source regions located in a semiconductor material that is formed on the substrate, wherein the drain and source regions have a recessed surface portion that is positioned at a lower height level compared to a height level defined by a surface of a gate insulation layer of the N-channel transistor. The semiconductor device further comprises a P-channel transistor formed above the substrate and comprising drain and source regions including a strain-inducing portion comprised of a semiconductor alloy. Moreover, a first strain-inducing layer is formed above the N-channel transistor, wherein the first strain-inducing layer induces a first type of strain in a channel region of the N-channel transistor. Finally, the semiconductor device comprises a second strain-inducing layer formed above the P-channel transistor, wherein the second strain-inducing layer provides a second type of strain in a channel region of the P-channel transistor, wherein the second type of strain differs from the first type of strain.

One illustrative method disclosed herein comprises selectively forming a semiconductor alloy in first recesses in a silicon-containing semiconductor layer that is laterally offset from a gate electrode of a first transistor. Moreover, the method comprises forming drain and source regions in the first transistor and a second transistor and selectively removing material of the silicon-containing layer in the drain and source regions of the second transistor while masking the first transistor and a gate electrode of the second transistor. Additionally, the method comprises forming a first strain-inducing layer above the first transistor and a second strain-inducing layer above the second transistor.

A further illustrative method disclosed herein comprises forming drain and source regions of a first transistor in a semiconductor layer adjacent to a first gate electrode having formed on sidewalls thereof a first spacer structure. The method further comprises forming drain and source regions of the second transistor adjacent to a second gate electrode having formed on sidewalls thereof a second spacer structure. Moreover, recesses are formed in the drain and source regions of the second transistor, while the first transistor is masked and the second spacer structure and a cap layer formed on the second gate electrode are used as an etch mask. The method further comprises reducing a width of the second spacer structure and forming a strain-inducing material above the first and second transistors.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1i schematically illustrate cross-sectional views of a semiconductor device comprising two transistor elements during various manufacturing stages in forming a recessed configuration in one of the transistors, while maintaining a substantially non-recessed configuration in the other transistor by using an efficient masking regime according to illustrative embodiments;

FIG. 1j schematically illustrates a cross-sectional view of the semiconductor device according to still further illustrative embodiments in which a recessed transistor configuration may be formed in one type of transistor such that a buried insulating layer may be exposed prior to the deposition of a strain-inducing material; and

FIG. 1k schematically illustrates a cross-sectional view of a semiconductor device in a manufacturing stage prior to forming recesses in drain and source areas on the basis of an adjusted spacer width according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and process techniques for selectively providing a recessed transistor configuration while maintaining a high degree of compatibility with sophisticated CMOS process techniques for forming advanced semiconductor devices. Due to the recessed drain and source configuration of one type of device, such as N-channel transistors, an enhanced surface topography may be provided for the subsequent deposition of a highly stressed dielectric material, such as a dielectric etch stop layer, an interlayer dielectric material and the like. That is, the recessed drain and source configuration may enable the positioning of the highly stressed dielectric material more closely to the channel region, even if a reduced layer thickness in other device regions may be required due to the restricted conformal deposition capabilities of plasma enhanced deposition processes under consideration. Thus, although, in total, a reduced amount of highly stressed dielectric material may be deposited, the amount of dielectric material positioned closely to the channel region at a height level that substantially corresponds to the height level of the channel region may be increased which, in combination with the generally enhanced lateral stress transfer, may provide a higher strain in the channel region, thereby contributing to enhanced charge carrier mobility and thus drive current capability of the transistor under consideration.

In addition, the recessed drain and source configuration may also provide an increased surface area that is available in a silicidation process which may therefore result in a reduced sheet resistance of the contact areas of the device, while also the enhanced amount of metal silicide may contribute to the strain-inducing mechanism. For example, in N-channel transistors, the metal silicide may enhance the overall tensile stress effect, thereby additionally improving the overall charge carrier mobility. Furthermore, in some illustrative aspects disclosed herein, the sidewall spacer structure used for defining the lateral dopant profile of the drain and source regions may be reduced in width after recessing portions of the drain and source regions, thereby additionally contributing to performance gain as the lateral distance of the metal silicide region and also of the strain-inducing material with respect to the channel region may be reduced. On the other hand, a desired source and drain configuration, for instance a substantially planar configuration or a raised drain and source configuration, may be maintained in other transistor elements, such as P-channel transistors, substantially without affecting the overall manufacturing flow and hence the characteristics of these transistors. In some illustrative aspects, these transistors may have included therein a highly efficient strain-inducing mechanism, which, in some illustrative embodiments, may be provided in the form of a strained semiconductor alloy, such as silicon/germanium material, which may be formed on the basis of well-established manufacturing techniques. However, in combination with a reduction in spacer width, overall performance of these transistors may also be enhanced since a metal silicide and an appropriately stressed dielectric material may be positioned more closely to the channel region of these transistors.

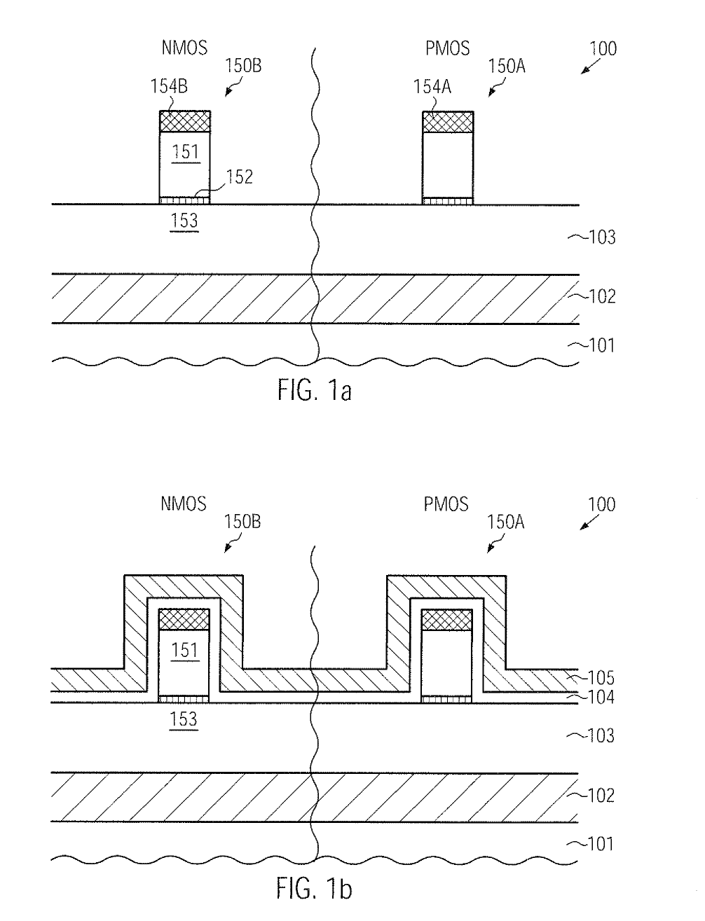

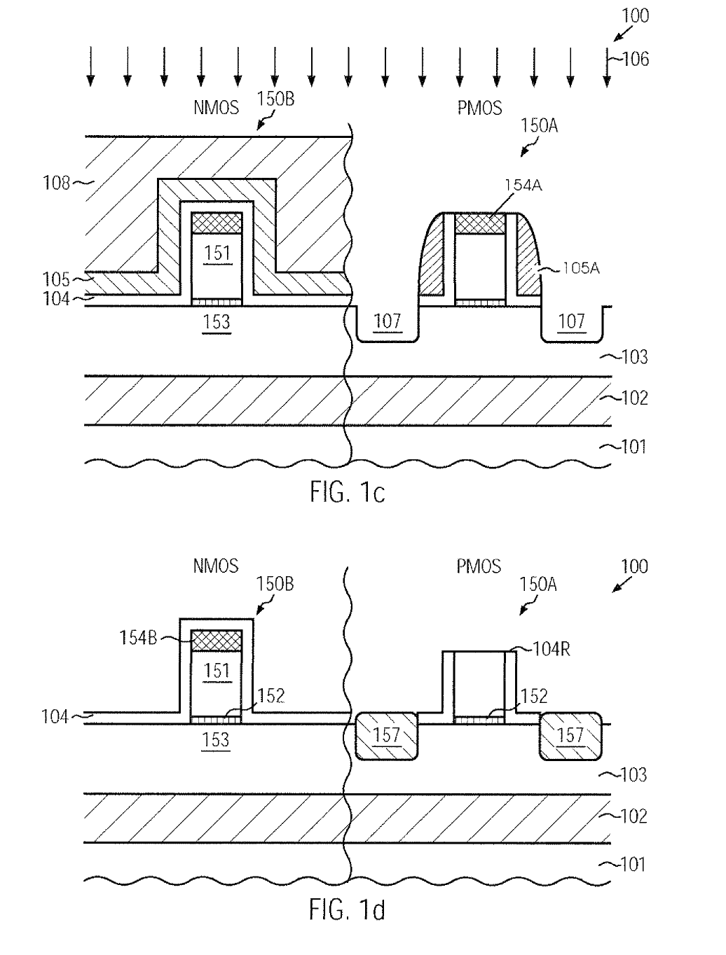

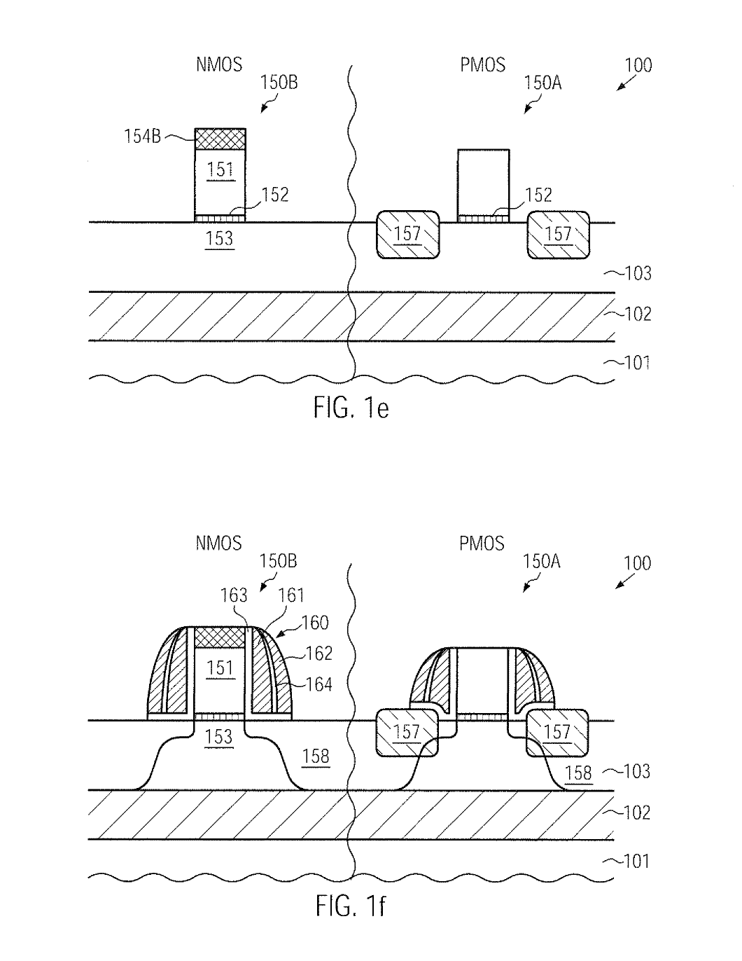

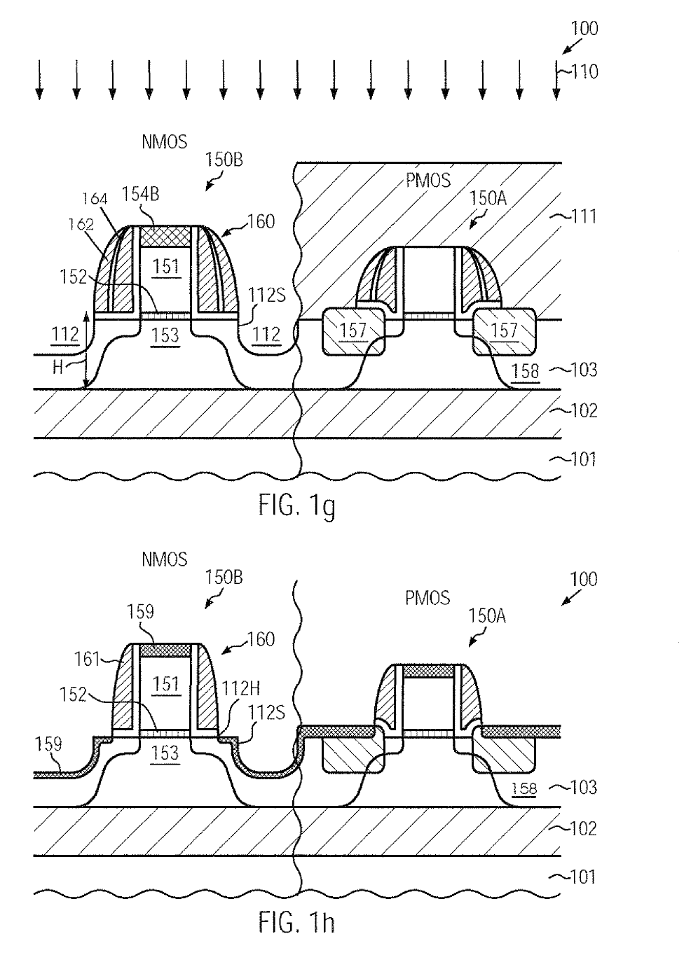

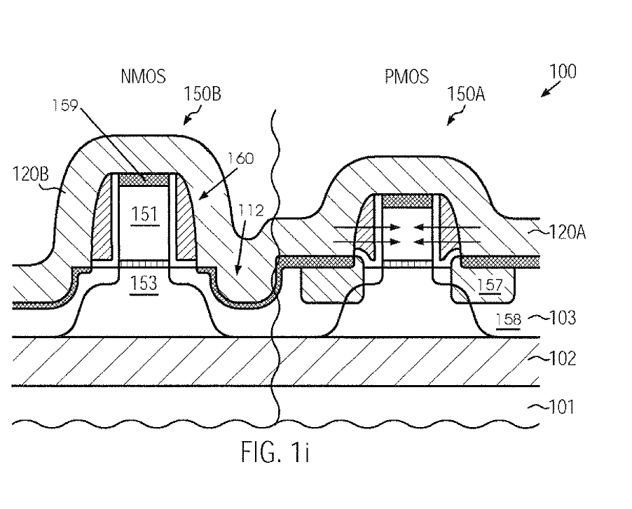

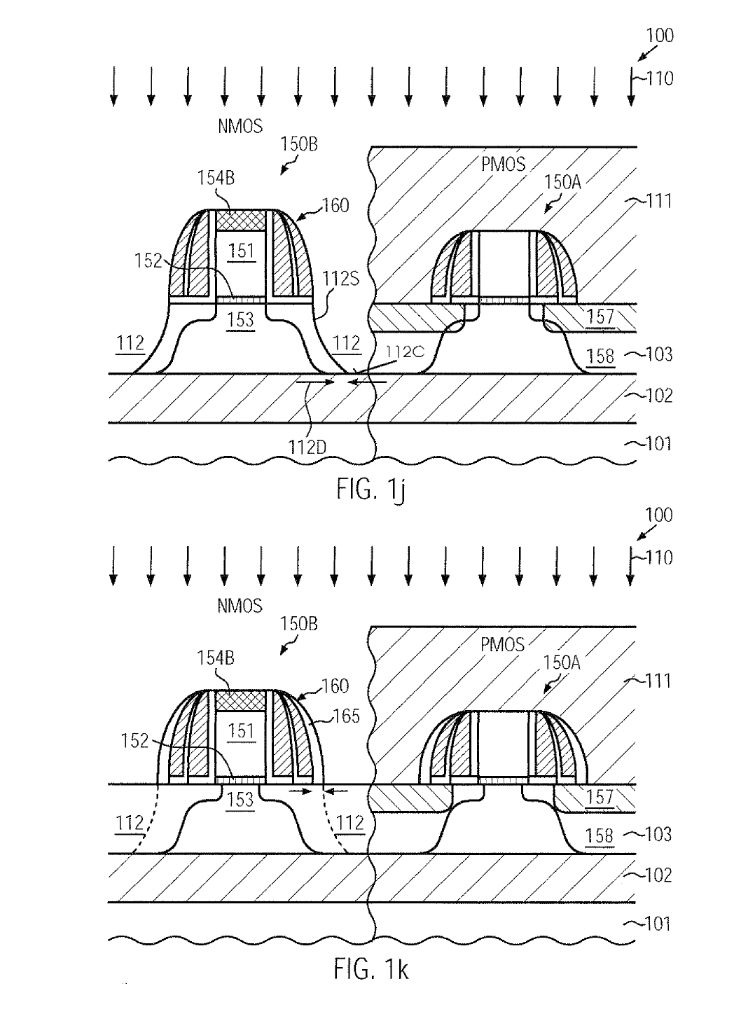

FIG. 1a schematically illustrates a cross-sectional view of a semiconductor device 100 comprising a substrate 101, above which is formed a silicon-containing semiconductor layer 103. The substrate 101 may represent any appropriate carrier material for forming thereabove the semiconductor layer 103. In one illustrative embodiment (not shown), the semiconductor layer 103 may represent an upper portion of the substrate 101, which may be provided, for instance, in the form of a silicon material and the like. In the embodiment shown in FIG. 1a, a buried insulating layer 102, for instance in the form of silicon dioxide, silicon oxynitride, silicon nitride and the like, may be provided between the substrate 101 and the semiconductor layer 103, thereby defining a silicon-on-insulator (SOI) configuration. It should be appreciated that the semiconductor layer 103 may have any appropriate composition and thickness as may be required for the formation of advanced transistor elements therein and thereon. For example, in the manufacturing stage shown in FIG. 1a, the semiconductor layer 103 may comprise dopant species, iso-electronic components or any other semiconductor-forming components in accordance with device requirements, wherein also a significant portion of silicon may be provided, the charge carrier mobility of which may be enhanced on the basis of mechanisms, as previously described. Moreover, the semiconductor device 100 may comprise a first transistor 150A and a second transistor 150B in an early manufacturing stage. The transistors 150A, 150B may comprise a gate electrode 151 which may be comprised of any appropriate material, such as polysilicon, or any other material which may be partially or completely replaced by another material in a later manufacturing stage and the like. The gate electrodes 151 may be separated from respective channel regions 153 by a gate insulation layer 152, which may be comprised of silicon dioxide, possibly in combination with other dielectric materials, such as nitrogen and the like, while, in other cases, high-k dielectric materials may be provided, depending on the overall device requirements. Furthermore, a cap layer 154A, 154B may be formed on the gate electrodes 151 of the first and second transistors 150A, 150B, respectively. The cap layers 154A, 154B may be comprised of any appropriate material having the required etch stop or etch delay capabilities as may be required in a later manufacturing stage for forming recesses in the first transistor, which may be refilled by an appropriate semiconductor alloy, and also during the formation of recesses in the second transistor 150B in a later stage, as will be described later in more detail. For example, the cap layers 154A, 154B may be provided in the form of a silicon nitride material, while other materials, such as silicon carbide, nitrogen-containing silicon carbide and the like, may be used.

The semiconductor device 100 as shown in FIG. 1a may be formed on the basis of the following processes. After forming appropriate isolation structures (not shown), such as shallow trench isolations, and defining appropriate basic dopant profiles, such as N-wells and P-wells, which may be accomplished on the basis of well-established CMOS process techniques, material for the gate insulation layer 152 and the gate electrodes 151 may be formed, for instance, by deposition, oxidation and the like. Furthermore, an appropriate material for the cap layers 154A, 154B may be provided, for instance, by depositing a silicon nitride material and the like. Thereafter, the material layers may be patterned on the basis of sophisticated lithography techniques, wherein, for instance, the cap layer material, possibly in combination with other materials for providing appropriate conditions during the lithography process, may be patterned and may be used as a hard mask for the further patterning of the gate electrodes 151 and the gate insulation layers 152.

FIG. 1b schematically illustrates the semiconductor device 100 in a further advanced manufacturing stage with an etch stop layer 104, which may be comprised of any appropriate material, such as silicon dioxide and the like, and which has a desired high etch selectivity with respect to a mask layer 105 comprised of a material that may be used as an etch mask and a growth mask during the subsequent manufacturing sequence. For instance, the mask layer 105 may be provided in the form of a silicon nitride material, a silicon carbide material and the like, as long as the desired etch selectivity with respect to the etch stop layer 104 may be accomplished. The layers 104, 105 may be provided with an appropriate thickness to obtain a desired lateral offset from the channel region 153 of the first transistor 150A.

The layers 104 and 105 may be formed on the basis of well-established deposition techniques. Next, an etch mask, such as a resist mask (not shown in FIG. 1b), may be provided to cover the second transistor 150B while exposing a portion of the layer 105 above the first transistor 150A to an appropriately designed etch ambient for removing material of the layer 105 from horizontal device portions. For example, an anisotropic etch process may be performed wherein, in one illustrative embodiment, a substantially non-selective etch recipe may be used with respect to the materials of the layers 104, 105 in order to obtain a desired sidewall spacer structure in the first transistor 150A, the width of which may be substantially determined by the initial thickness of the layers 104, 105 and the conditions of the etch process. In other illustrative embodiments, the etch process may be performed on the basis of a selective etch chemistry for substantially stopping the first etch step on the etch stop layer 104, wherein, in a subsequent step, exposed portions of the layer 104 may be removed by a separate etch step, for instance on the basis of a wet chemical process, a plasma-assisted process and the like. For example, selective anisotropic etch recipes for silicon nitride with respect to silicon dioxide are well established in the art. During an etch step for removing exposed portions of the etch step layer 104, the cap layer 154A and the material of the gate electrode 151 and the silicon-containing semiconductor layer 103 may also act as efficient etch stop materials. For example, a plurality of highly selective etch recipes for removing silicon dioxide selectively to silicon nitride and silicon are available and may be used.

FIG. 1c schematically illustrates the semiconductor device 100 after the above-described process sequence and during an etch process 106, which may be designed to remove material of the silicon-containing layer 103 selectively with respect to the cap layer 154A and a spacer structure 105A which may be comprised of the remaining portions of the layers 105 and 104 in the first transistor 150A, as previously explained. Consequently, during the etch process 106, recesses or cavities 107 may be formed in the layer 103, wherein a shape may be determined by the width of the spacer structure 105A and the conditions during the etch process 106. That is, depending on the device requirements, substantially isotropic behavior or a substantially anisotropic etch behavior (as shown) or any intermediate behavior may be adjusted during the process 106 to define the amount and position of a semiconductor alloy to be formed in the cavities 107. It should be appreciated that, in the embodiment shown, a resist mask 108, which may have been used for forming the spacer structure 105A, as previously explained, may still be present during the etch process 106, thereby reducing undue material removal of the layer 105 in the second transistor 150B if an etch selectivity thereof may be less pronounced with respect to the etch process 106. In other cases, the resist mask 108 may be removed after forming the spacer structure 105A and the process 106 may be performed by using the mask layer 105 as an efficient etch mask.

In still other illustrative embodiments, the etch process 106 comprises appropriate steps which may be performed on the basis of the resist mask 108 so as to anisotropically etch the mask layer 104, obtaining respective spacer elements, followed by an etch process for removing exposed portions of the etch stop layer 104 with a subsequent etch step for etching into the semiconductor layer 103, wherein at least two of the respective process steps may be performed in the same etch chamber while appropriately selecting an etch ambient during the various etch steps. Consequently, the provision of the etch stop layer 104 may be appropriately incorporated into the overall process flow for forming the mask layer 105 substantially without adding additional process complexity.

FIG. 1d schematically illustrates the semiconductor device 100 in an advanced manufacturing stage. As illustrated, a semiconductor alloy 157, such as silicon/germanium, may be formed in the cavities 107, wherein the semiconductor alloy 157 may be formed up to any desired height level to provide a substantially planar configuration or a raised drain and source configuration, depending on the overall requirements. It should be appreciated that the semiconductor alloy 157 may, if considered appropriate, include an appropriate cap material, such as silicon, if the presence of an increased amount of germanium or any other alloy-forming component may be considered inappropriate at the surface portion during the further processing of the device 100. The semiconductor alloy 157 may be formed on the basis of a selective epitaxial growth technique which may be performed after removing the resist mask 108, if provided during the etch process 106, on the basis of an appropriate deposition ambient in which the semiconductor alloy material may substantially deposit on exposed surface portions of the layer 103, while deposition on dielectric areas, such as the mask layer 104, the cap layer 154A and the sidewall spacer 105A, may be suppressed. Appropriate deposition techniques are well established in the art and may be used for this purpose. Next, the remaining portion of the mask layer 104 may be removed, for instance by performing a selective etch process, such as a removal process based on hot phosphoric acid, thereby also removing a portion of the spacer structure 105A, when comprised of silicon nitride. Furthermore during this removal process, the cap layer 154A, if comprised of a material having similar etch characteristics compared to the mask layer material 104, may be removed. Thus, after a respective selective etch process, the mask layer 104 may be removed from the second transistor 150B, thereby exposing the etch stop layer 104, which may efficiently suppress undesired material removal of the cap layer 154B. On the other hand, the cap layer 154A and a portion of the spacer structure 105A may be removed while the layer 104 in the first transistor 150A may also act as an etch stop material, the thickness of which may, however, be reduced compared to the material 104 in the second transistor 150B due to the increased exposure to the corresponding etch ambient. Next, the etch stop layer 104, 104R may be removed from the second and first transistors 150B, 150A by performing a selective etch process, which may be performed on the basis of hydrofluoric acid (HF), when the etch stop material 104 is comprised of silicon dioxide. In other cases, any other appropriate etch chemistry may be used for selectively removing the etch stop material 104 with respect to the gate electrodes 151, the semiconductor layer 103 and the semiconductor alloy 157.

FIG. 1e schematically illustrates the semiconductor device 100 after the above-described process sequence. Hence, the gate electrode 151 of the second transistor 150b may still be covered by the cap layer 154B, which may, therefore, be used as an efficient etch mask in a later manufacturing stage for forming recesses in the second transistor 150B.

FIG. 1f schematically illustrates the semiconductor device 100 in a further advanced manufacturing stage. As shown, a sidewall spacer structure 160 may be formed on sidewalls of the gate electrode 151, wherein, in some illustrative embodiments, the spacer structure 160 may comprise a plurality of individual spacer elements 161, 162, which may be separated from the gate electrode 151 and from each other by etch stop liners 163 and 164. In some illustrative embodiments, at least the outermost spacer element 162 may be comprised of substantially the same material as the cap layer 154B, which is to be understood such that the cap layer 154B and the outermost spacer 162 may have substantially the same etch characteristic during a subsequent etch process for reducing a width of the spacer structure 160. In other illustrative embodiments, any other material composition may be used for the spacers 161, 162 as long as a desired etch selectivity of the spacer structure 160 and the cap layer 154B on the one hand with respect to the semiconductor layer 103 on the other hand may be achieved during a process for recessing the semiconductor layer 103 in the second transistor 150B in a later manufacturing stage. For example, the spacer elements 161, 162 may be comprised of silicon nitride, while the liner materials 163 and 164 may be comprised of silicon dioxide. Furthermore, the transistors 150A, 150B may have formed in portions of the semiconductor layer 103, drain and source regions 158 having a lateral dopant profile in accordance with device requirements, wherein the lateral dopant profile may be substantially determined by the configuration of the spacer structure 160 and respective process parameters used for forming the drain and source regions 158. That is, the spacer structure 160 may typically be formed in several manufacturing stages, for instance by first providing an offset spacer (not shown), which may provide a desired lateral offset of a first portion of the drain and source regions 158, which may define a shallow PN junction. Thereafter, for instance, the spacer element 161 may be formed in combination with the liner 163 on the basis of well-established deposition and anisotropic etch techniques, followed by an appropriate implantation process for incorporating an appropriate dopant species based on suitable process parameters, such as dose and energy, wherein implantation energy may determine the depth distribution, while the width of the spacer element 161 substantially defines the lateral position of the dopant species. Next, the outer spacer element 162 may formed in combination with the liner 164 by deposition and anisotropic etch processes followed by a further implantation sequence for incorporating the dopant species for defining a portion of the drain and source regions 158, wherein the final dopant profile may be adjusted on the basis of anneal processes to activate the dopant species and also re-crystallize implantation-induced damage.

For example, as shown in FIG. 1f, the process parameters of the preceding implantation processes and the anneal cycle(s) may be adjusted such that the drain and source regions 158 may extend substantially down to the buried insulating layer 102, while, in other cases, any other appropriate depth may be adjusted. It should be appreciated that the formation of the drain and source regions 158 may involve additional implantation processes, such as forming a halo region (not shown), which may involve the incorporation of a dopant species of inverse conductivity type with respect to the dopant species used for defining the drain and source regions 158 so as to obtain the desired dopant gradient at the respective PN junctions. Similarly, pre-amorphization implantation processes may be performed if deemed appropriate.

FIG. 1g schematically illustrates the semiconductor device 100 in an advanced manufacturing stage in which an etch mask 111, such as a resist mask, may be provided to cover the first transistor 150A, while exposing the second transistor 150B to an etch ambient 110. The etch ambient 110 may be established on the basis of an etch chemistry that enables selective removal of the semiconductor layer 103 with respect to the spacer structure 160 and the cap layer 154B. For example, substantially the same process conditions may be applied as have previously been used during the formation of the cavities 107 (FIG. 1c), wherein, in the embodiment shown, however, the process parameters may be selected such that undue under-etching of the spacer structure 160 may be avoided. Consequently, recesses 112 may be provided which may have a lateral size that may be reliably within the drain and source regions 158 to provide a sufficient process margin for the formation of metal silicide on exposed surfaces 112S of the recesses 112 without “shorting” the PN junctions of the drain and source regions 158. Hence, a recessed drain and source configuration may be obtained in the second transistor 150B, wherein at least a significant portion of the surface 112S is positioned at a height level that is lower compared to a height level defined by the gate insulation layer 152.

In this context, a positional information is to be understood as a relative position with respect to a pronounced surface of the device 100, such as an interface between the buried insulating layer 102 and the semiconductor layer 103, wherein a component is “lower” than another component if the distance between the former component and reference plane, i.e., the above-specified interface, is less compared to a distance of the later component and the reference plane. In this sense, the height level H corresponding to the gate insulation layer 152, for instance to the interface between the layer 152 and the channel region 153, may define an upper limit for the surface 112S. Hence, since the surface 112S may define a border of the drain and source regions 158, at least a significant portion of which is located below a height level defined by the gate insulation layer 152, the transistor 150B may be considered as a transistor having a recessed drain and source configuration. On the other hand, the first transistor 150A may have a substantially planar configuration when the drain and source regions 158 thereof, including the semiconductor alloy 157, may substantially extend to the height level H while a raised drain and source configuration may be understood as a structure in which at least portions of the drain and source regions 158, such as the semiconductor alloy 157, may extend above the height level H, as, for instance, shown in FIG. 1g.

After forming the recesses 112 by the etch process 110, the resist mask 111 may be removed, for instance, by well-established plasma-assisted etch techniques, followed by the removal of the cap layer 154B, which may be accomplished on the basis of any appropriate selective etch process. In one illustrative embodiment, an etch chemistry may be used for removing the cap layer 154B selectively to the gate electrode 151, while also etching the spacer structure 160 in order to reduce a width thereof. In this case, the liner 164 may act as an efficient etch stop material, thereby providing a highly controllable reduction of the width of the spacer structure 160. In one embodiment, the cap layer 154B and at least the outermost spacer 162 may have a similar etch behavior, thereby enabling an efficient simultaneous removal of these components, while nevertheless providing a high degree of process uniformity.

FIG. 1h schematically illustrates the semiconductor device 100 in a further advanced manufacturing stage in which, after the removal of the cap layer 154B and the spacer 162, a metal silicide material 159 may be formed in exposed portions of the gate electrode 151 and the drain and source regions 158. Due to the reduction of the width of the spacer structure 160, for instance by removing the outermost spacer 162, the drain and source regions 158 may comprise a horizontal surface portion 112H, in addition to the recessed surface portion 112S, which may be available for converting silicon material into a highly conductive metal silicide of the regions 159. Similarly, in the first transistor 150A, the silicon region 159 may be positioned close to the channel region 153, wherein a distance thereof is substantially determined by the reduced spacer structure 160. As previously explained, in the second transistor 150B, the increased surface portion compared to a substantially planar configuration may provide an enhanced amount of metal silicide, thereby also providing a reduced series resistance of the transistor 150B, wherein the reduced offset to the channel region 153 may additionally provide enhanced device performance, as previously explained. Furthermore, the recessed configuration of the drain and source regions 158 may create a certain tensile strain component in the channel region 152 of the transistor 150B caused by the metal silicide 159, wherein a respective strain caused by the metal silicide may be significantly less pronounced in the transistor 150A, due to the non-recessed or even raised drain and source configuration.

The metal silicide 159 may be formed on the basis of well-established process techniques, for instance, involving the deposition of a refractory metal, such as nickel, platinum, cobalt and the like, followed by an appropriate heat treatment, in combination with the removal of non-reacted metal.

FIG. 1i schematically illustrates the semiconductor device 100 in a further advanced manufacturing stage in which a strain-inducing material may be formed above the first and second transistors 150A, 150B. In one illustrative embodiment, the strain-inducing material may be provided in the form of a first strain-inducing layer 120A formed above the transistor 150A and inducing a strain as required for increasing the charge carrier mobility in the channel region 153 of the first transistor 150A. On the other hand, a second strain-inducing layer 120B may be formed above the second transistor 150B, thereby inducing a different type of strain in the channel region 153 thereof to enhance the charge carrier mobility therein. In one illustrative embodiment, the first transistor 150A may represent a P-channel transistor requiring a compressive strain to enhance hole mobility for a standard crystallographic configuration of the semiconductor layer 103. Similarly, the second transistor 150B may represent an N-channel transistor wherein a tensile stress component of the layer 120B, in combination with a tensile stress component of the metal silicide 159, may provide enhanced electron mobility in the channel region 153 of the transistor 150B. The strain-inducing layers 120A, 120B may be provided in the form of any appropriate material, such as silicon nitride, nitrogen-containing silicon carbide, silicon dioxide and the like. For example, as previously explained, the layers 120A, 120B may be provided in the form of a silicon nitride material deposited on the basis of appropriately selected process parameters so as to obtain the desired internal stress level. In still other illustrative embodiments, in addition or alternatively to the layers 120A, 120B, one or more layers of dielectric material may be positioned with a desired internal stress level so as to obtain the desired overall transistor performance. For example, for the recessed configuration of the transistor 150B, the material of the layer 120B may be positioned within the recesses 112 in a highly stressed state, thereby obtaining an increased lateral stress component acting on the channel region 153. Furthermore, due to the previous reduction of the width of the spacer structure 160, stressed material above the height level H (FIG. 1g) may be positioned closer to the channel region compared to conventional strategies in which spacer width reduction may be omitted. Similarly, the material of the strain-inducing layer 120A may be positioned close to the channel region 153 of the transistor 150A, while an efficient strain-inducing mechanism may also be maintained by the semiconductor alloy 157. Additionally, the series resistance in the transistor 150A may also be reduced, due to the close proximity of the metal silicide region 159 with respect to the PN junctions of the drain and source regions 158.

The strain-inducing material, such as the layers 120A, 120B, may be provided on the basis of any appropriate process technique. For example, one of the layers 120A, 120B may be formed, possibly in combination with an etch stop material (not shown), and may be subsequently removed from one of the transistors that requires the other type of strain. Thereafter, the other one of the layers 120A, 120B may be deposited and an unwanted portion thereof may be selectively removed, for instance, on the basis of appropriate etch stop or etch indicator materials from the other one of the transistors 150A, 150B. It should be appreciated that additional strain-inducing materials or substantially stress-neutral materials may be added, depending upon the overall process requirements. Furthermore, additional interlayer dielectric material may be deposited, for instance, in the form of silicon dioxide, and contact openings may be subsequently patterned in the interlayer dielectric material and the strain-inducing material, such as the layers 120A, 120B.

FIG. 1j schematically illustrates the semiconductor device 100 according to further illustrative embodiments, wherein the etch process 110 for forming the recesses 112 may be performed such that the recesses 112 may extend substantially down to the buried insulating layer 102, thereby providing enhanced stress transfer characteristics and also reducing the parasitic capacitance of the PN junctions in the drain and source regions 158 of the second transistor 150B. For this purpose, the process parameters may be adjusted to obtain a sidewall or surface portion 112S resulting in a distance 112D between the PN junction of the drain and source region 158 and the surface 112C at the buried insulating layer 102, which still provides a sufficient process margin during a subsequent process for forming the metal silicide 159. That is, the distance 112D may be such that a shorting of the drain and source region 158 in the vicinity of the buried insulating layer 102 may be reliably prevented after consuming silicon-containing material in this area by the silicidation process. Moreover, the inclined nature of the surface 112S may also provide a reliable contact scenario when forming respective contact openings to the drain and source regions 158, wherein at least a portion of the respective contact openings may expose a portion of the inclined surface 112S.

FIG. 1k schematically illustrates the semiconductor device 100 according to still further illustrative embodiments in which, prior to the etch process 110, the width of the spacer structure 160 may be adjusted in view of shaping and positioning the recesses 112. In one illustrative embodiment, the spacer structure 160 may obtain a further spacer element 165, thereby providing an increased process margin when forming the recesses 112 followed by the formation of the metal silicide 159, in particular when the recesses 112 are to be formed so as to extend down to the buried insulating layer 102.

As a result, the present disclosure provides semiconductor devices and manufacturing techniques in which a strain-inducing mechanism may be selectively provided on the basis of a recessed drain and source configuration without negatively affecting the planar or raised drain and source configuration of other transistors, while also providing reduced distance of metal silicide material and a highly stressed dielectric material with respect to the channel region of recessed and non-recessed transistors. Consequently, performance of recessed and non-recessed transistors may be enhanced while nevertheless providing a high degree of compatibility with conventional sophisticated CMOS techniques. Thus, a recessed drain and source configuration may, for instance, be provided for N-channel transistors, thereby providing reduced series resistance and enhanced stress transfer efficiency, while efficient strain-inducing mechanisms may be used in P-channel transistors, such as an embedded semiconductor alloy, while reduced series resistance in combination with enhanced efficiency of a further strain-inducing mechanism in the form of a stressed dielectric material may also be accomplished. For this purpose, an appropriate masking regime may enable the selective recessing of one type of transistor while not substantially affecting the other type of transistor.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
an N-channel transistor formed above a substrate, said N-channel transistor comprising drain and source regions located in a semiconductor material, said drain and source regions having a recessed surface portion that is positioned at a lower height level compared to a height level defined by a surface of a gate insulation layer of said N-channel transistor;
a P-channel transistor formed above said substrate and comprising drain and source regions, said drain and source regions of said P-channel transistor comprising a strain-inducing portion comprised of a semiconductor alloy;
a first strain-inducing layer formed above said N-channel transistor, said first strain-inducing layer inducing a first type of strain in a channel region of said N-channel transistor; and
a second strain-inducing layer formed above said P-channel transistor, said second strain-inducing layer inducing a second type of strain other than said first type in a channel region of said P-channel transistor.

2. The semiconductor device of claim 1, wherein said recessed surface portion is laterally offset from a spacer structure formed on sidewalls of a gate electrode of said N-channel transistor.

3. The semiconductor device of claim 1, further comprising a metal silicide material formed on said recessed surface portion, said metal silicide material extending along said offset to said sidewall spacer structure.

4. The semiconductor device of claim 3, further comprising a buried insulating layer formed below said semiconductor material.

5. The semiconductor device of claim 4, wherein said first strain-inducing layer is separated from said buried insulating layer at said drain and source regions of said N-channel transistor by at least one of said semiconductor material and said metal silicide material.

6. The semiconductor device of claim 4, wherein said first strain-inducing layer is in contact with said buried insulating layer at said drain and source regions of said N-channel transistor.

7. The semiconductor device of claim 1, wherein said drain and source regions of said P-channel transistor define a non-recessed drain and source configuration with respect to a height level defined by a gate insulation layer of said P-channel transistor.

8. A method, comprising:
selectively forming a semiconductor alloy in a plurality of first recesses in a silicon-containing semiconductor layer laterally offset from a gate electrode of a first transistor;
forming drain and source regions for said first transistor and a second transistor;
selectively removing material of said silicon-containing semiconductor layer in the drain and source regions of said second transistor while masking said first transistor and a gate electrode of said second transistor; and
forming a first strain-inducing layer above said first transistor and a second strain-inducing layer above said second transistor.

9. The method of claim 8, further comprising forming said gate electrodes of said first and second transistors to provide a cap layer on a top surface of said gate electrodes and maintaining said cap layer on the gate electrode of said second transistor when selectively removing material of said silicon-containing semiconductor layer.

10. The method of claim 9, further comprising forming an etch stop layer above said first and second transistors, forming a mask layer above said etch stop layer, masking said second transistor and performing an etch process to form a spacer element on sidewalls of the gate electrode of said first transistor.

11. The method of claim 10, further comprising forming said first recesses by performing an etch sequence while using said spacer element and the cap layer on the gate electrode of said first transistor as an etch mask.

12. The method of claim 11, wherein selectively forming said semiconductor alloy in said first recesses comprises epitaxially growing material while using said spacer element and said cap layer as a growth mask for the first transistor and using said mask layer as a growth mask for said second transistor.

13. The method of claim 12, further comprising removing an outer portion of said spacer element and said cap layer on the gate electrode of said first transistor by using said etch stop layer as an etch stop material.

14. The method of claim 13, further comprising selectively removing said etch stop layer to expose said cap layer formed on the gate electrode of said second transistor.

15. The method of claim 8, wherein forming said drain and source regions comprises forming a sidewall spacer structure on the sidewalls of the gate electrodes of the first and second transistors and using said sidewall spacer structure as an implantation mask for adjusting a lateral dopant profile of the drain and source regions of said first and second transistors.

16. The method of claim 15, further comprising reducing a width of said sidewall spacer structure after selectively removing material of said silicon-containing semiconductor layer for forming second recesses.

17. The method of claim 16, further comprising forming a metal silicide in said second recesses and a portion of said silicon-containing semiconductor layer that is exposed by reducing the width of said sidewall spacer structure.

18. The method of claim 8, wherein material of said silicon-containing semiconductor layer is removed until a portion of a buried insulating layer is exposed.

19. A method, comprising:
forming drain and source regions of a first transistor in a semiconductor layer adjacent to a first gate electrode having formed on sidewalls thereof a first spacer structure;
forming drain and source regions of a second transistor adjacent to a second gate electrode having formed on sidewalls thereof a second spacer structure;
forming recesses in the drain and source regions of said second transistor while masking said first transistor and using said second spacer structure and a cap layer formed on said second gate electrode as an etch mask;
reducing a width of said second spacer structure; and
forming a strain-inducing material above said first and second transistors.

20. The method of claim 19, further comprising forming a metal silicide in said first and second transistors by using said spacer structure of reduced width as a mask.

21. The method of claim 19, further comprising adapting a width of said spacer structure to adjust an offset of said recesses after forming said drain and source regions.

22. The method of claim 21, wherein adapting said width comprises increasing said width prior to forming said recesses.

23. The method of claim 19, further comprising forming cavities adjacent to said first gate electrode structure and filling said cavities with a semiconductor alloy prior to completing the drain and source regions of said first transistor.
